(19) United States
(12) Patent Application Publication
(10) Pub. No.: US 2026/0247542 A1
(43) Pub. Date: Aug. 20, 2026

(54) METHOD OF MANUFACTURING METAL LAYER HAVING INCREASED OXIDATION RESISTANCE AND METHOD OF MANUFACTURING SEMICONDUCTOR PACKAGE

(71) Applicant: Samsung Electronics Co., Ltd., Suwon-si (KR)

(72) Inventors: Jakyoung Gu, Suwon-si (KR); Sungwng Kim, Suwon-si (KR); Seungwoo Park, Suwon-si (KR); Kyoungok Jung, Suwon-si (KR); Hyeyeong Jo, Suwon-si (KR)

(73) Assignee: Research & Business Foundation Sungkyunkwan University, Suwon-si (KR)

(21) Appl. No.: 19/395,454

(22) Filed: Nov. 20, 2025

(30) Foreign Application Priority Data
Feb. 14, 2025 (KR) 10-2025-0019343
Apr. 25, 2025 (KR) 10-2025-0054228

(51) Int. Cl. H05K 3/12; H01B 13/00; H10W 70/00

(52) U.S. Cl. CPC H05K 3/1283; H01B 13/0036; H10W 70/099

(57) ABSTRACT

A method of manufacturing a metal layer having increased oxidation resistance is presented. The method includes allowing an electride layer and a metal layer to be in contact with each other and annealing the electride layer and the metal layer such that the metal layer is reduced by the electride layer.

### CROSS-REFERENCE TO RELATED APPLICATION(S)

This application claims benefit of priority to Korean Patent Application No. 10-2025-0054228 filed on April 25, 2025 in the Korean Intellectual Property Office and Korean Patent Application No. 10-2025-0019343 filed on February 14, 2025 in the Korean Intellectual Property Office, the disclosures of which are incorporated herein by reference in their entirety.

### BACKGROUND

Semiconductor chips and semiconductor packages embedded in electronic products may include multiple metal layers which forms an electrical signal path. Surface oxidation of a metal layer may cause migration, reduced adhesion of a dielectric layer, or the like. Accordingly, a processing technique to prevent oxidation of a metal layer or to remove an oxide layer has been developed. Such post-processing processes may increase, however, manufacturing costs and time.

### SUMMARY

Some example implementations of the present disclosure is to provide a method of manufacturing a metal layer having increased oxidation resistance and a method of manufacturing a semiconductor package.

According to example implementations of the present disclosure, a method of manufacturing a metal layer having increased oxidation resistance includes contacting an electride layer and a metal layer with each other; and annealing the electride layer and the metal layer such that the metal layer is reduced by the electride layer.

According to example implementations of the present disclosure, a method of manufacturing a metal layer having increased oxidation resistance includes contacting an electride layer and a metal layer with each other; and annealing the electride layer and the metal layer such that the metal layer is reduced by the electride layer, wherein a work function of the metal layer after the annealing is lower than a work function of the metal layer before the annealing.

According to example implementations of the present disclosure, a method of manufacturing a semiconductor package includes forming a first metal pad on a carrier substrate; forming a metal pattern on the first metal pad; forming a second metal pad on the metal pattern, the second metal pad electrically connected to the first metal pad through the metal pattern; and applying a process of changing a work function to at least one of the first metal pad, the second metal pad, or the metal pattern, wherein the process of changing a work function includes allowing an electride layer to be in contact with at least one of the first metal pad, the second metal pad, or the metal pattern, and performing annealing.

The process of changing a work function is performed immediately after one of forming the first metal pad, forming the metal pattern, or forming the second metal pad.

At least one of the first metal pad, the second metal pad, or the metal pattern to which the process of changing a work function is applied has a work function lower than a work function of a raw-material metal thereof.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a method of manufacturing a metal layer having increased oxidation resistance according to some example implementations of the present disclosure;

FIGS. 2A and 2B are graphs indicating changes in a work function of a metal layer according to some example implementations of the present disclosure;

FIG. 3A is a cross-sectional diagram illustrating a semiconductor package according to some example implementations of the present disclosure;

FIG. 3B is an enlarged diagram illustrating region “A” in FIG. 3A;

FIGS. 4, 5, 6, 7, 8, 9 and 10, are diagrams illustrating method of manufacturing a semiconductor package according to some example implementations of the present disclosure;

FIG. 11 is a cross-sectional diagram illustrating a semiconductor package according to some example implementations of the present disclosure;

FIG. 12 is a cross-sectional diagram illustrating a semiconductor package according to some example implementations of the present disclosure;

FIGS. 13 and 14 are diagrams illustrating a method of manufacturing a semiconductor package according to some example implementations of the present disclosure;

FIG. 15 is a cross-sectional diagram illustrating a semiconductor package according to some example implementations of the present disclosure;

FIG. 16 is a cross-sectional diagram illustrating a semiconductor package according to some example implementations of the present disclosure; and

FIG. 17 is a cross-sectional diagram illustrating a semiconductor package according to some example implementations of the present disclosure.

### DETAILED DESCRIPTION

Hereinafter, implementations of the present disclosure will be described as follows with reference to the accompanying drawings.

Unless otherwise indicated, in example implementations, “upper,” “upper surface,” lower,” “lower surface,” “side surface,” or the like, are based on the drawings, and may be varied in the direction in which elements are disposed.

The terms “first,” “second,” or the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example implementations.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

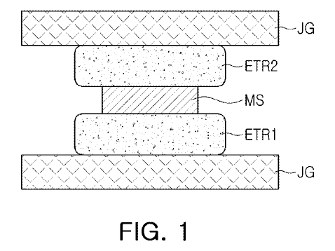

FIG. 1 is a diagram illustrating a method of manufacturing a metal layer having increased oxidation resistance according to some example implementations.

Referring to FIG. 1, a method of manufacturing a metal layer having increased oxidation resistance in some example implementations may include: contacting electride layers ETR1 and ETR2 and a metal layer MS with each other; and annealing the electride layers ETR1 and ETR2 and the metal layer MS such that the metal layer MS is reduced by the electrides ETR1 and ETR2.

In some example implementations, the electride layers ETR1 and ETR2 may be in contact with at least one surface of the metal layer MS.

According to some example implementations, after the annealing, a work function of the metal layer MS may be reduced further than a work function of the metal layer MS before the annealing. Accordingly, oxidation resistance may increase and electrical reliability may improve.

In some example implementations, the electride layers ETR1 and ETR2 may have a form of bulk, single crystal, or thin film. The electride layers ETR1 and ETR2 may include an ionic compound having a work function lower than a work function of the metal layer MS. For example, the electride layers ETR1 and ETR2 may include at least one of calcium nitride (Ca₂N), strontium nitride (Sr₂N), barium nitride (Ba₂N), yttrium carbide (Y₂C), gadolinium carbide (Gd₂C), hafnium sulfide (Hf₂S), titanium sulfide (Ti₂S), or calcium oxide-alumina (12CaO·7Al₂O₃ or C₁₂A₇ for short).

In some example implementations, the metal layer MS may include at least one of copper (Cu), aluminum (Al), iron (Fe), silver (Ag), tin (Sn), gold (Au), nickel (Ni), lead (Pb), or titanium (Ti), or alloys thereof.

In some example implementations, the electride layers ETR1 and ETR2 and the metal layer MS may be in contact with each other under a vacuum condition.

In some example implementations, the annealing may be performed in a thermal environment of about 100°C to about 800°C. Also, the annealing may be performed under a vacuum condition. Also, the annealing may be performed for about 1 hour or more, for example, in a range of about 1 hour to about 30 hours, about 10 hours to about 30 hours, or about 10 hours to about 20 hours.

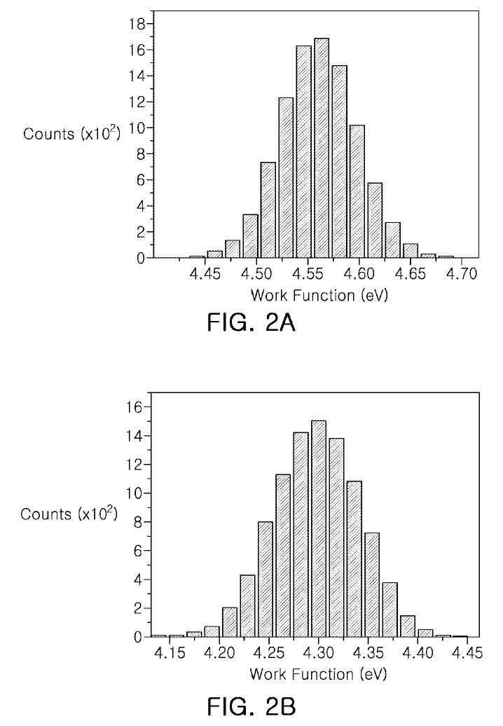

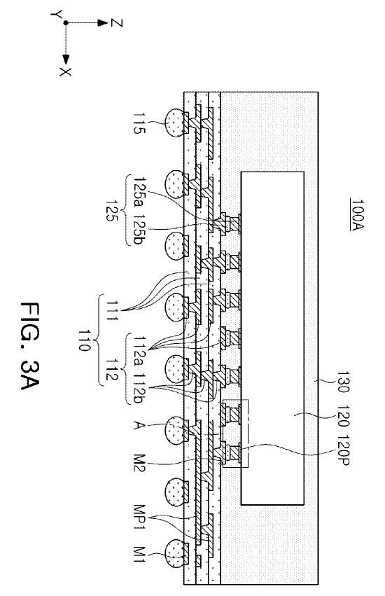

FIGS. 2A and 2B are graphs indicating changes in a work function of a metal layer according to some example implementations.

A method of manufacturing a metal layer (abbreviated as “process of changing a work function”) in some example implementations was applied to the metal layer MS. In the example implementations, the first electride layer ETR1 was in contact with an upper surface of the metal layer MS, and the second electride layer ETR2 was in contact with a lower surface of the metal layer MS.

After allowing the first electride layer ETR1 and the second electride layer ETR2 to be in contact with the metal layer MS, annealing was performed at about 200°C for 12 hours in a vacuum.

As the metal layer MS, a copper (Cu) foil having a thickness of about 2 μm was prepared.

As the first electride layer ETR1 and the second electride layer ETR2, a gadolinium carbide (Gd₂C) thin film was prepared.

A work function of the metal layer MS before and after annealing was measured using ultraviolet photoelectron spectroscopy (UPS).

Referring to FIGS. 2A and 2B, a change in the work function of the metal layer MS before and after annealing may be indicated. The work function of the metal layer MS before annealing may be indicated in the graph in FIG. 2A. The work function of the metal layer MS after annealing may be indicated in the graph in FIG. 2B. The work function of the metal layer MS after annealing was about 4.30 eV, which was lower than the work function of the metal layer MS before annealing (about 4.56 eV). As described above, electrons transferred from the first electride layer ETR1 and the second electride layer ETR2 may be present in or on the metal layer MS, and oxidation resistance of the metal layer MS may be increased.

Hereinafter, electronic components implemented by applying the method of manufacturing a metal layer in some example implementations will be described. The semiconductor chip and the semiconductor package described below may be understood as some example implementations to which the method of manufacturing a metal layer in some example implementations is applied.

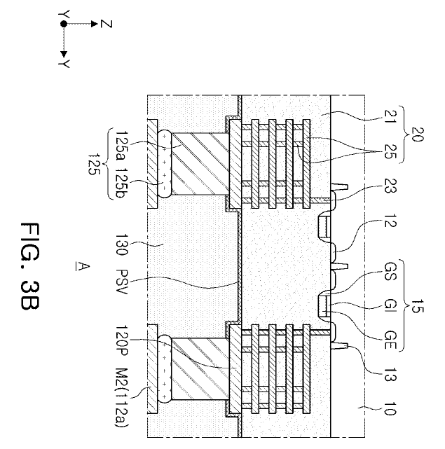

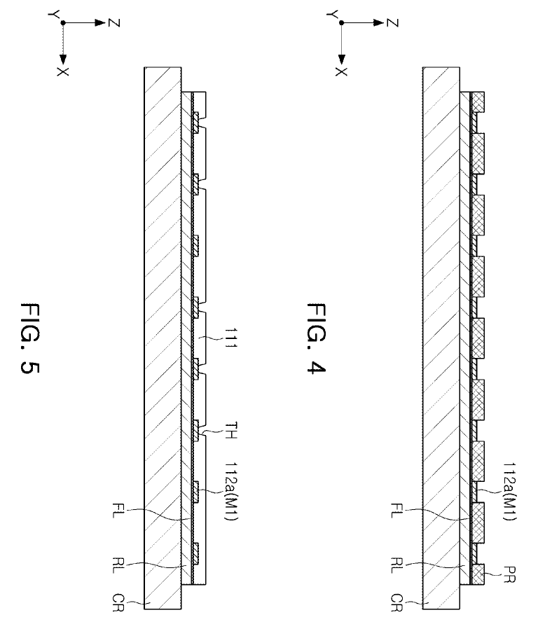

FIG. 3A is a cross-sectional diagram illustrating a semiconductor package 100A according to some example implementations. FIG. 3B is an enlarged diagram illustrating region “A” in FIG. 3A.

Referring to FIGS. 3A and 3B, a semiconductor package 100A in some example implementations may include a substrate 110 and a semiconductor chip 120. In example implementations, the semiconductor package 100A may further include a mold layer 130. According to some example implementations, the semiconductor package 100A may include metal layers which may receive electrons from the electride such that a work function may be reduced and may have increased oxidation resistance and increased electrical reliability. Hereinafter, elements of the semiconductor package 100A including the metal layers having a reduced work function will be described.

Here, the electride may be understood as an ionic compound in the form of a bulk, single crystal, or thin film, which may include a high density of interlayer electrons and may have a low work function. For example, the electride may include an inorganic electrons transfer agent such as calcium nitride ([Ca₂N]⁺·e⁻), strontium nitride ([Sr₂N]⁺·e⁻), barium nitride ([Ba₂N]⁺·e⁻), yttrium carbide ([Y₂C]²⁺·2e⁻), gadolinium carbide ([Gd₂C]²⁺·2e⁻), hafnium sulfide ([Hf₂S]²⁺·2e⁻), titanium sulfide ([Ti₂S]²⁺·2e⁻), calcium oxide-alumina ([C₁₂A₇ or 12CaO·7Al₂O₃)]²⁺·2e⁻), or the like.

The substrate 110 (or “first substrate”) may be a support substrate on which a semiconductor chip 120 is mounted, and may include an insulating layer 111 and redistribution conductors 112. The substrate 110 may be electrically connected to a module substrate, a system board, or the like, through connection bumps 115.

The insulating layer 111 may surround at least a portion of each of the redistribution conductors 112 and may electrically isolate the redistribution conductors 112 spaced apart from each other. The insulating layer 111 may include an insulating resin. The insulating resin may include a thermosetting resin such as an epoxy resin, a thermoplastic resin such as a polyimide, or a resin impregnated with an inorganic pillar, for example, a prepreg, an Ajinomoto build-up film (ABF), a flame retardant (FR)-4, or a bismaleimide-triazine (BT). In some example implementations, the insulating layer 111 may include a photosensitive resin such as a photo-imageable dielectric (PID). The insulating layer 111 may include a plurality of insulating layers stacked in the vertical direction (Z-direction). Depending on the processes, a boundary between the plurality of insulating layers may not be distinct.

The redistribution conductors 112 may redistribute connection pads 120P of the semiconductor chip 120. The redistribution conductors 112 may include, for example, copper (Cu), aluminum (Al), iron (Fe), silver (Ag), tin (Sn), gold (Au), nickel (Ni), lead (Pb), titanium (Ti), or alloys thereof. In some example implementations, the redistribution conductors 112 may include copper (Cu) or alloys thereof. The redistribution conductors 112 may provide a transfer path for a power signal, ground signal, data signal, or the like.

Each of the redistribution conductors 112 may include a redistribution pattern 112a and a redistribution via 112b. The redistribution pattern 112a may extend in the horizontal direction (X- and Y-direction) in the insulating layer 111 and may redistribute the connection pads 120P to a fan-out region. The redistribution pattern 112a may be provided in more or fewer layers than the example illustrated in the drawing.

The redistribution via 112b may be formed integrally with the corresponding redistribution pattern 112a. The redistribution via 112b may be a filled via in which a metal material is filled in a via hole or a conformal via in which a metal material extends along an inner wall of a via hole. The redistribution via 112b may be formed to electrically connect the redistribution patterns 112a spaced apart from each other in the vertical direction (Z-direction).

In some example implementations, the substrate 110 may include a first metal pad M1, a second metal pad M2, and a metal pattern MP1 provided by redistribution conductors 112. The first metal pad M1 may be understood as a lower pad of the substrate 110 on which connection bumps 115 are disposed. The second metal pad M2 may be understood as an upper pad of the substrate 110 disposed opposite to the first metal pad M1, that is, a pad on which the semiconductor chip 120 is mounted. The metal pattern MP1 may be understood as a portion of a conductor including the redistribution pattern 112a or a redistribution via 112b integrally connected to the redistribution pattern 112a. The metal pattern MP1 may be formed to electrically connect the first metal pad M1 to the second metal pad M2.

The connection bumps 115 may be disposed on the first metal pad M1 of the substrate 110. The connection bumps 115 may be electrically connected to a module substrate, a system board, or the like. The connection bumps 115 may include, for example, tin (Sn) or an alloy including tin (Sn) (e.g., Sn-Ag, Sn-Ag-Cu).

The semiconductor chip 120 may include a logic chip such as a central processor (CPU), a graphic processor (GPU), a field programmable gate array (FPGA), an application processor (AP), a digital signal processor, an encryption processor, a microprocessor, a microcontroller, an analog-to-digital converter, an application-specific IC (ASIC), or a memory chip including a volatile memory such as a dynamic RAM (DRAM), a static RAM (SRAM), and a non-volatile memory such as a phase change RAM (PRAM), a magnetic RAM (MRAM), a resistive RAM (RRAM), and a flash memory.

The semiconductor chip 120 may be disposed on the substrate 110 and may include a connection pad 120P electrically connected to the second metal pad M2 of the substrate 110. The connection pad 120P may include at least one metal selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), or an alloy including two or more metals. The connection pad 120P may include, for example, aluminum (Al) or an aluminum (Al) alloy, but example implementations thereof are not limited thereto. The connection pad 120P may be electrically connected to the second metal pad M2 through a bump structure 125.

The bump structure 125 may be disposed on the second metal pad M2 of the substrate 110. The bump structure 125 may electrically connect the connection pad 120P of the semiconductor chip 120 to the second metal pad M2 of the substrate 110. The bump structure 125 may include a pillar 125a on the connection pad 120P, and a solder ball 125b between the pillar 125a and the second metal pad M2. The pillar 125a may include at least one metal selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn), or an alloy including two or more metals. The solder ball 125b may be formed of tin (Sn) or an alloy including tin (Sn), for example, an alloy including at least two or more of tin (Sn), lead (Pb), silver (Ag), copper (Cu), and bismuth (Bi). In example implementations, the bump structure 125 may include only one of the pillar 125a or the solder ball 125b. In some example implementations, the connection pad 120P may be connected to the second metal pad M2 through a bonding wire.

As illustrated in FIG. 3B, the semiconductor chip 120 may further include a semiconductor substrate 10, and a circuit layer 20 on which an integrated circuit is formed.

The semiconductor substrate 10 may be a semiconductor wafer. The semiconductor substrate 10 may include, for example, a semiconductor element such as silicon, germanium, or a compound semiconductor such as silicon carbide (SiC), gallium arsenide (GaAs), indium arsenide (InAs), and indium phosphide (InP). The semiconductor substrate 10 may include a conductive region 12 and an isolation region 13 formed on one surface. The conductive region 12 may be, for example, a well doped with impurities, or a structure doped with impurities. The isolation region 13 may be a device isolation structure having a shallow trench isolation (STI) structure, and may include silicon oxide. The other surface of the semiconductor substrate 10 may be covered with an insulating film formed of silicon oxide, silicon nitride, a polymer, or a combination thereof.

The individual devices ID may be electrically connected to the conductive region 12 of the semiconductor substrate 10. The individual devices ID may include various active devices and/or passive devices, such as, for example, a FET such as a planar FET or a FinFET, a memory device such as a flash memory, a DRAM, a SRAM, an EEPROM, a PRAM, a MRAM, a FeRAM, and a RRAM, a logic device such as an AND, an OR, and a NOT, and a system LSI, CIS, and MEMS. The individual devices ID may include a gate structure 15. The gate structure 15 may include a gate insulating layer GI, a gate electrode GE disposed on the gate insulating layer GI, and a gate spacer GS surrounding the gate insulating layer GI and the gate electrode GE. The gate insulating layer GI may include silicon oxide or silicon nitride. The gate electrode GE may include a semiconductor material, a metal material, or the like. The gate spacer GS may be formed of a silicon oxide film, a silicon nitride film, a silicon carbide film, or a combination thereof.

The circuit layer 20 may be disposed on one surface of the semiconductor substrate 10 on which the conductive region 12 is formed. The circuit layer 20 may include an interlayer insulating layer 21 and a metal wiring 25. The interlayer insulating layer 21 may be formed to cover the individual devices ID and the metal wiring 25 and may electrically isolate the individual devices ID disposed on the semiconductor substrate 10. The interlayer insulating layer 21 may include flowable oxide (FOX), tonen silazen (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), high density plasma oxide (HDP), plasma enhanced oxide (PEOX), flowable CVD oxide (FCVD), or a combination thereof. At least a partial region of the interlayer insulating layer 21 surrounding the metal wiring 25 may include a low-κ layer. The interlayer insulating layer 21 may be formed using a chemical vapor deposition (CVD), a flowable-CVD process, or a spin coating process.

The metal wiring 25 may be disposed between the connection pad 120P and the semiconductor substrate 10, and may electrically connect the connection pad 120P to the individual device ID and the conductive region 12. The metal wiring 25 may be connected to the individual devices ID and the conductive region 12 by an interconnection portion 23 (e.g., a contact plug). The metal wiring 25 may be formed by a damascene process. The metal wiring 25 may be formed as a multilayer structure including metal patterns and metal vias formed of, for example, aluminum (Al), gold (Au), cobalt (Co), copper (Cu), nickel (Ni), lead (Pb), tantalum (Ta), tellurium (Te), titanium (Ti), tungsten (W), or a combination thereof. A barrier film including titanium (Ti), titanium nitride (TiN), tantalum (Ta), or tantalum nitride (TaN) may be disposed between the metal wiring 25 and the interlayer insulating layer 21. In example implementations, the semiconductor chip 120 may further include a passivation layer PSV covering the connection pad 120P. The passivation layer PSV may include at least one of silicon oxide or silicon nitride.

The semiconductor chip 120 may be a bare semiconductor chip, but example implementations thereof are not limited thereto, and the semiconductor chip 120 may also be a packaged-type semiconductor chip. For example, the semiconductor chip 120 may further include an additional metal wiring between the connection pad 120P and the bump structure 125 illustrated in FIG. 3B. The additional metal wiring may include a material similar to that of the metal wiring 25.

The mold layer 130 may cover at least a portion of the semiconductor chip 120 on the substrate 110. The mold layer 130 may include an insulating resin, such as, for example, an epoxy molding compound (EMC). The mold layer 130 may fill a lower portion of the semiconductor chip 120 in a molded underfill (MUF) manner. In some example implementations, an underfill in a capillary underfill (CUF) manner may be formed in a lower portion of the semiconductor chip 120.

According to some example implementations, at least one metal element among the above-mentioned elements may receive electrons from an electride and may have a work function lower than a work function of the raw-material metal. That is, each of the first metal pad M1, the second metal pad M2, or the metal pattern MP1 of the substrate 110, and the connection pad 120P, or the metal wiring 25 of the semiconductor chip 120 include a raw-material metal, and at least one of the above-mentioned components may have a work function lower than a work function of the respective raw-material metal. Here, the “work function” of the raw-material metal may indicate a range of a general work function determined by a crystal structure, Miller index, or the like.

The first metal pad M1, the second metal pad M2, the metal pattern MP1, the connection pad 120P, and the metal wiring 25 may include the same type or different types of metals as raw materials. That is, at least one of the first metal pad M1, the second metal pad M2, the metal pattern MP1, the connection pad 120P, or the metal wiring 25 may include a metal different from the other components. The first metal pad M1, the second metal pad M2, the metal pattern MP1, the connection pad 120P, and the metal wiring 25 may include at least one metal or an alloy including two or more metals selected from a group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), cobalt (Co), tantalum (Ta), tellurium (Te), tungsten (W), and zinc (Zn).

In some example implementations, the first metal pad M1 and the second metal pad M2 may include a first metal. At least one of the first metal pad M1 or the second metal pad M2 may have a work function lower than a work function of the first metal. For example, the first metal may include copper (Cu), and the work function of the first metal may be in a range of about 4.4 eV to about 4.9 eV, and the work function of at least one of the first metal pad M1 or the second metal pad M2 may be less than about 4.4 eV, for example, more than about 1 eV and less than about 4.4 eV, more than about 2 eV and less than about 4.4 eV, more than about 3 eV and less than about 4.4 eV, or the like.

In some example implementations, the first metal pad M1, the second metal pad M2, and the metal pattern MP1 may include a first metal. At least one of the first metal pad M1, the second metal pad M2, or the metal pattern MP1 may have a work function lower than a work function of the first metal. In an example, the first metal may include copper (Cu), and the work function of the first metal may be in a range of about 4.4 eV to about 4.9 eV, and at least one of the first metal pad M1, the second metal pad M2, or the metal pattern MP1 may be less than about 4.4 eV. For example, the first metal may include copper (Cu), and the work function of the metal pattern MP1 may be greater than the work functions of the first metal pad M1 and the second metal pad M2. The first metal pad M1 and the second metal pad M2 may be less than about 4.4 eV, and the work function of the metal pattern MP1 may be about 4.4 eV or more.

In some example implementations, the first metal pad M1, the second metal pad M2, the metal pattern MP1, and the metal wiring 25 may include a first metal. At least one of the first metal pad M1, the second metal pad M2, the metal pattern MP1, or the metal wiring 25 may have a work function less than a work function of the first metal. For example, the first metal may include copper (Cu), and the work function of the first metal may be in a range of about 4.4 eV to about 4.9 eV, and at least one of the first metal pad M1, the second metal pad M2, the metal pattern MP1, or the metal wiring 25 may have a work function less than about 4.4 eV.

In some example implementations, the metal wiring 25 may include a first metal, and the connection pad 120P may include a second metal. The metal wiring 25 may have a work function lower than a work function of the first metal. The connection pad 120P may have a work function lower than a work function of the second metal. For example, the first metal may include copper (Cu), and the second metal may include aluminum (Al). The work function of the first metal may be in a range of about 4.4 eV to about 4.9 eV, and the work function of the second metal may be in a range of about 4.06 eV to about 4.26 eV. The work function of the metal wiring 25 may be less than about 4.4 eV. The work function of the connection pad 120P may be less than about 4.06 eV, for example, in a range of more than about 1 eV and less than about 4.06 eV, more than about 2 eV and less than about 4.06 eV, more than about 3 eV and less than about 4.06 eV, or the like.

In some example implementations, the bump structure 125 may include a pillar 125a including a first metal and a solder ball 125b including a second metal. The pillar 125a may have a work function less than a work function of the first metal. Alternatively, the solder ball 125b may have a work function less than a work function of the second metal. For example, the first metal may include copper (Cu) and the second metal may include a tin-silver alloy (Sn-Ag). The work function of the first metal may be in a range of about 4.4 eV to about 4.9 eV, and the work function of the second metal may be in a range of about 4.2 eV to about 4.6 eV. The work function of the pillar 125a may be less than about 4.4 eV. The work function of the solder ball 125b may be less than about 4.2 eV, for example, in a range of more than about 1 eV and less than about 4.2 eV, more than about 2 eV and less than about 4.2 eV, more than about 3 eV and less than about 4.2 eV, or the like.

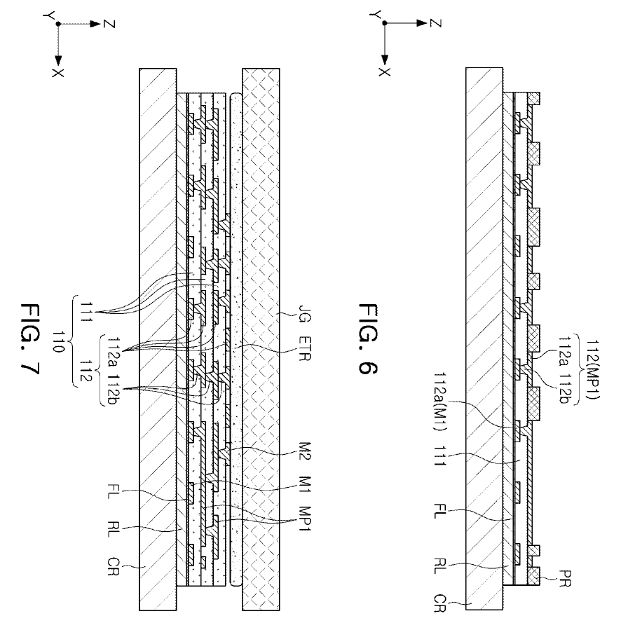

FIGS. 4, 5, 6, 7, 8, 9 and 10 are diagrams illustrating method of manufacturing a semiconductor package 100A according to some example implementations.

Referring to FIG. 4, a redistribution pattern 112a may be formed on a carrier substrate CR. The carrier substrate CR may be a temporary support including a glass wafer, a curable resin layer, or the like. A release layer RL and a thin film layer FL may be stacked in order on the carrier substrate CR. The thin film layer FL may be conformally formed on a surface of the release layer RL by a deposition process. The thin film layer FL may be a double layer including titanium (Ti) and copper (Cu). The redistribution pattern 112a may be formed by a plating process using the thin film layer FL as a seed. The redistribution pattern 112a may be formed in a photosensitive material layer PR patterned by a photolithography process. The redistribution pattern 112a may include a first metal pad M1 including copper (Cu).

Referring to FIG. 5, subsequently, the photosensitive material layer PR may be removed by an ashing process, and an insulating layer 111 may be formed. The insulating layer 111 may be formed using a photosensitive resin such as PID. The insulating layer 111 may include via holes TH formed by a photolithography process. In example implementations, a process of changing a work function may be applied to the first metal pad M1, which will be described later with reference to FIG. 7.

Referring to FIG. 6, a redistribution conductor 112 may be formed. The redistribution conductor 112 may include a redistribution pattern 112a on the insulating layer 111 and a redistribution via 112b in the via hole TH of the insulating layer 111. The redistribution conductor 112 may be formed by a plating process. The redistribution conductor 112 may include copper (Cu) or alloys thereof. Thereafter, the photosensitive material layer PR may be removed by an ashing process. The redistribution conductor 112 may include a metal pattern MP1 connected to the first metal pad M1.

Referring to FIG. 7, by repeating the above-described process (FIGS. 5 and 6), a substrate 110 may be formed. The substrate 110 may include an insulating layer 111 and a redistribution conductor 112. The redistribution conductor 112 may include a first metal pad M1, a second metal pad M2, and a metal pattern MP1. In some example implementations, a process of changing a work function may be applied to the redistribution conductor 112. The “process of changing a work function” mentioned in the example implementations may be understood as an annealing process of transferring electrons of the electride layer ETR to a target metal layer in a predetermined thermal environment (about 100°C to about 300°C) after allowing the electride layer ETR to be in direct contact with the target metal layer. The annealing process may be performed under a vacuum condition, but example implementations thereof are not limited thereto. For example, the electride layer ETR (e.g., gadolinium carbide (Gd₂C)) attached to a jig JG may be connected to the second metal pad M2 in an upper portion of the substrate 110, and annealing may be performed at about 200°C. The annealed second metal pad M2 may have a work function (less than 4.4 eV) lower than a work function of copper (Cu) (about 4.4 eV to about 4.9 eV), and oxidation resistance may be increased. In example implementations, when the “process of changing a work function” is applied in the operation in FIG. 4 and/or FIG. 6, the first metal pad M1 and/or the metal pattern MP1 may also have a work function (less than 4.4 eV) lower than the work function of copper (Cu) (about 4.4 eV to about 4.9 eV).

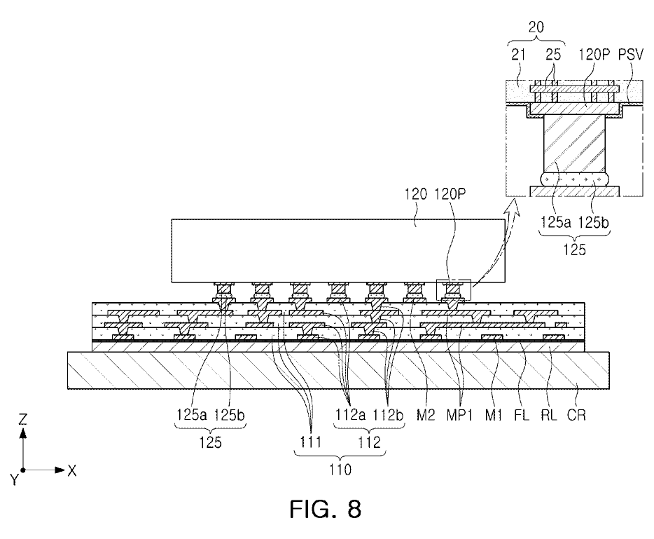

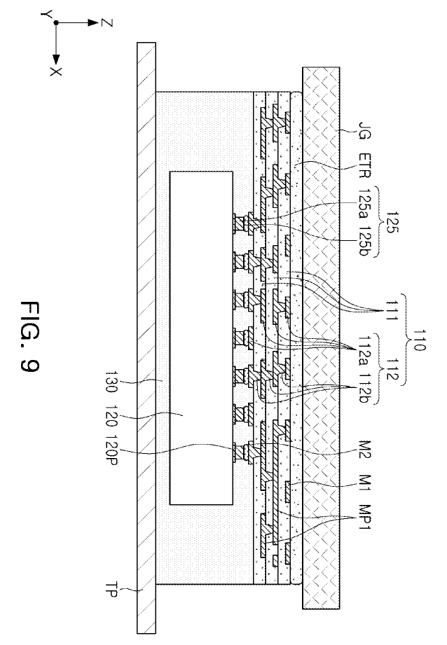

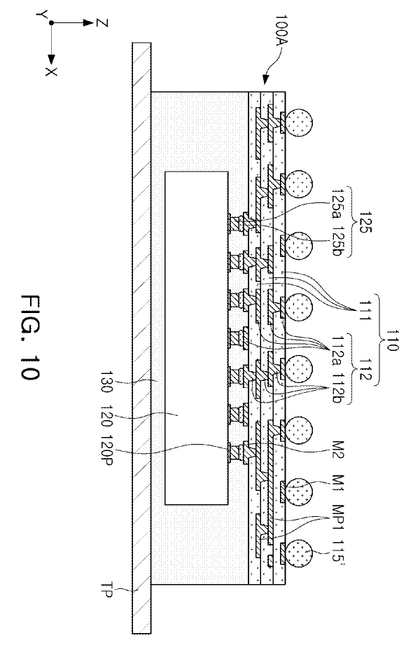

Referring to FIG. 8, a semiconductor chip 120 may be mounted on a substrate 110. The semiconductor chip 120 may be flip-chip bonded to a second metal pad M2. A connection pad 120P may be connected to the second metal pad M2 through a bump structure 125. In some example implementations, in the semiconductor chip 120, the “process of changing a work function” may be applied to the connection pad 120P and/or the metal wiring 25 connected to the connection pad 120P. For example, the semiconductor chip 120 may include a metal wiring 25 having a work function (less than 4.4 eV) lower than a work function of copper (Cu) (about 4.4 eV to about 4.9 eV), or may include a connection pad 120P having a work function (less than 4.06 eV) lower than a work function of aluminum (Al) (about 4.06 eV to about 4.26 eV).

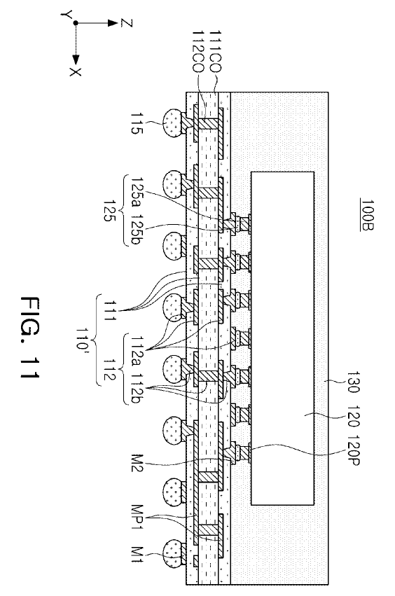

Referring to FIG. 9, a mold layer 130 may be formed. The mold layer 130 may encapsulate the semiconductor chip 120. The mold layer 130 may be formed by applying and curing a molding material such as EMC. Subsequently, the carrier substrate CR may be removed, and a support tape TP may be attached to the mold layer 130. In some example implementations, a process of changing a work function may be applied to the first metal pad M1. In this case, even when the process of changing a work function is not applied in the operation in FIG. 4, the first metal pad M1 may have a work function (less than 4.4 eV) lower than the work function of copper (Cu) (about 4.4 eV to about 4.9 eV).

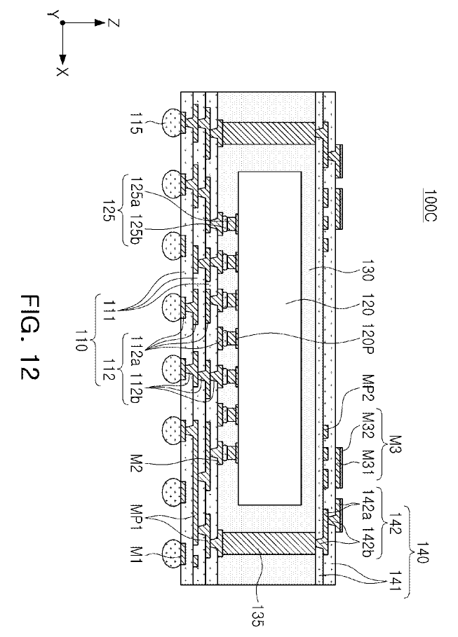

Referring to FIG. 10, preliminary bumps 115’ may be formed on the first metal pad M1. The preliminary bumps 115’ may be solder balls to which a process of changing a work function is applied. In some example implementations, the preliminary bumps 115’ may be formed by stencil-printing solder paste. In this case, the process of changing a work function may be applied to the preliminary bumps 115’ as illustrated in FIG. 9. As described above, according to some example implementations, a semiconductor package 100A including metal layers having a reduced work function and increased oxidation resistance and electrical reliability by receiving electrons from an electride may be formed.

FIG. 11 is a cross-sectional diagram illustrating a semiconductor package 100B according to some example implementations.

Referring to FIG. 11, a semiconductor package 100B in some example implementations may be configured the same as or similar to the examples described with reference to FIGS. 3A, 3B, 4, 5, 6, 7, 8, 9 and 10, other than the shape of the substrate 110’. In some example implementations, the substrate 110’ may include a core insulating layer 111CO. The core insulating layer 111CO may include a material which may improve stiffness of the substrate 110’. For example, the core insulating layer 111CO may be formed using a copper clad laminate (CCL), an unclad CCL, a glass substrate, or a ceramic substrate. The metal pattern MP1 may be formed on both surfaces of the core insulating layer 111CO. Depending on designs, the substrate 110’ may have a multilayer core substrate structure in which a plurality of core insulating layers 111CO are stacked. A thickness of the core insulating layer 111CO may be greater than a thickness of the insulating layer 111 stacked thereabove and therebelow. The core via 112CO penetrating the core insulating layer 111CO may be a via hole completely filled with a conductive material, or a conductive material may be conformally formed along a wall of the via hole. When the core via 112CO is conformally formed, an inner space of the core via 112CO may be filled with an insulating material such as an epoxy resin.

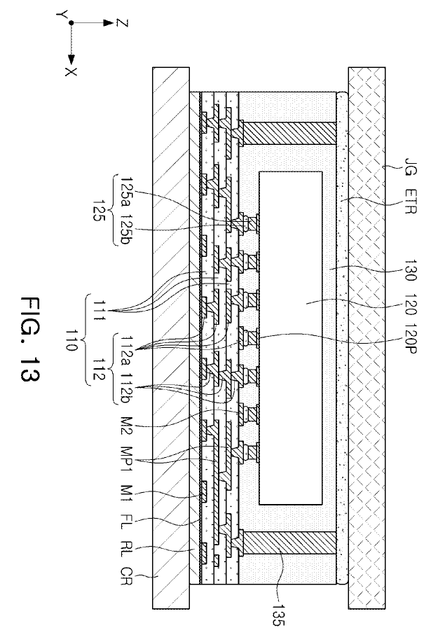

FIG. 12 is a cross-sectional diagram illustrating a semiconductor package 100C according to some example implementations.

Referring to FIG. 12, the semiconductor package 100C in some example implementations may be configured the same as or similar to the examples described with reference to FIGS. 3A, 3B, 4, 5, 6, 7, 8, 9, 10 and 11, other than the configuration in which a metal post 135 and a second substrate 140 are further included.

The metal post 135 may be disposed around the semiconductor chip 120. The metal post 135 may be disposed in the mold layer 130 to electrically connect the first redistribution conductor 112 to the second redistribution conductor 142. The metal post 135 may include, for example, copper (Cu), aluminum (Al), silver (Ag), tin (Sn), gold (Au), nickel (Ni), lead (Pb), titanium (Ti), or alloys thereof. The metal post 135 may have a cylindrical shape extending in the vertical direction (Z-direction), but some implementations thereof are not limited thereto.

In some example implementations, the metal post 135 may include a first metal. A work function of the metal post 135 may be lower than a work function of the first metal. For example, the first metal may include copper (Cu), the work function of the first metal may be in a range of about 4.4 eV to about 4.9 eV, and the work function of the metal post 135 may be less than about 4.4 eV.

The second substrate 140 may be disposed on the mold layer 130 and may include a second insulating layer 141 and a second redistribution conductor 142. The second insulating layer 141 and the second redistribution conductor 142 may be configured the same as or similar to the first insulating layer 111 and the first redistribution conductor 112 of the first substrate 110, and thus, an overlapping description will not be provided.

In some example implementations, the second substrate 140 may include a third metal pad M3 provided by the second redistribution conductors 142, and a second metal pattern MP2. The third metal pad M3 may be understood as an upper pad of the second substrate 140. The second metal pattern MP2 may be understood as a portion of a conductor including the second redistribution pattern 142a or the second redistribution via 142b integrally connected to the second redistribution pattern 142a. The second metal pattern MP2 may be formed to electrically connect the third metal pad M3 to the metal post 135.

In some example implementations, the third metal pad M3 may include a first metal. A work function of the third metal pad M3 may be lower than a work function of the first metal. For example, the first metal may include copper (Cu), a work function of the first metal may be in a range of about 4.4 eV to about 4.9 eV, and a work function of the third metal pad M3 may be less than about 4.4 eV.

In some example implementations, the third metal pad M3 may include a base layer M31 and a protective layer M32 on the base layer M31. The base layer M31 may include a first metal, and the protective layer M32 may include a second metal. A work function of the base layer M31 may be lower than a work function of the first metal. A work function of the protective layer M32 may be lower than a work function of the second metal. The first metal may include copper (Cu), and a work function of the first metal may be in a range of about 4.4 eV to about 4.9 eV, and a work function of the base layer M31 may be less than about 4.4 eV. The second metal may include at least one of nickel (Ni) and gold (Au). The protective layer M32 may be a double thin film in which nickel (Ni) and gold (Au) are stacked in order. For example, the protective layer M32 may have a work function lower than a work function of an uppermost thin film, that is, a work function of gold (Au) (about 5.1 eV to about 5.47 eV).

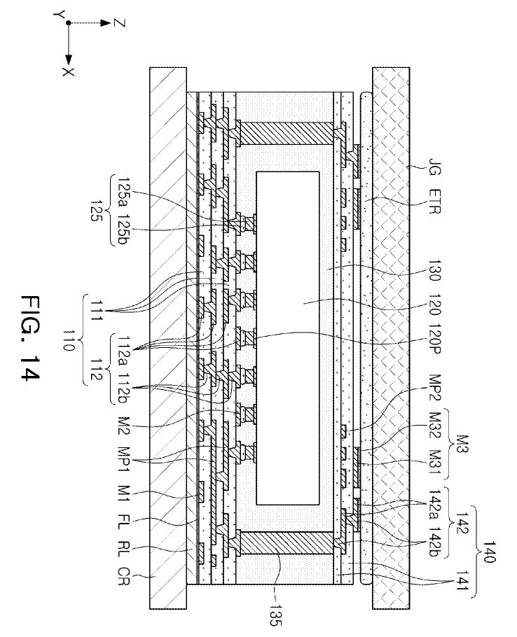

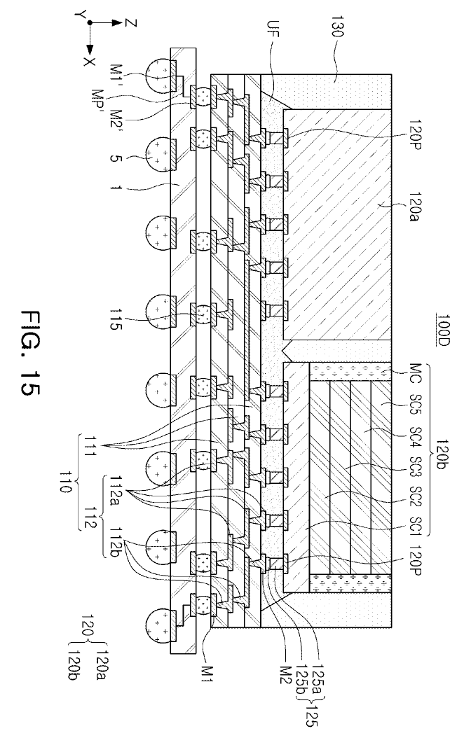

FIGS. 13 and 14 are diagrams illustrating a method of manufacturing a semiconductor package according to some example implementations.

Referring to FIG. 13, a metal post 135 and a mold layer 130 may be formed on a substrate 110. The substrate 110 may be formed by the processes in FIGS. 4, 5, 6 and 7 described above. A semiconductor chip 120 may be mounted after the metal post 135 is formed. The metal post 135 may be exposed to an upper portion of the planarized mold layer 130. In some example implementations, a process of changing a work function may be applied to the metal post 135. An electride layer ETR (e.g., gadolinium carbide (Gd₂C)) may be connected to the metal post 135 exposed to the mold layer 130, and annealing may be performed at about 200°C. The annealed metal post 135 may have a work function (less than 4.4 eV) lower than a work function of copper (Cu) (about 4.4 eV to about 4.9 eV), and oxidation resistance may be increased. In example implementations, a “process of changing a work function” may be applied by allowing the electride layer ETR to be in contact with a side surface of the metal post 135 before the mold layer 130 is formed.

Referring to FIG. 14, a second substrate 140 may be formed. The second substrate 140 may include a second insulating layer 141 and a second redistribution conductor 142. The second substrate 140 may be formed by repeating a process similar to the process of forming the first substrate 110. In some example implementations, the process of changing a work function may be applied to a third metal pad M3. An electride layer ETR (e.g., gadolinium carbide (Gd₂C)) may be connected to the protective layer M32 of the third metal pad M3, and annealing may be performed at about 200°C. The annealed protective layer M32 may have a work function (less than 5.1 eV) lower than a work function (about 5.1 eV to about 5.47 eV) of gold (Au), and oxidation resistance may be increased. In some example implementations, when a “process of changing a work function” is applied to the second metal pattern MP2, the second metal pattern MP2 may have a work function of less than 4.4 eV (about 4.4 eV to about 4.9 eV) lower than a work function of copper (Cu).

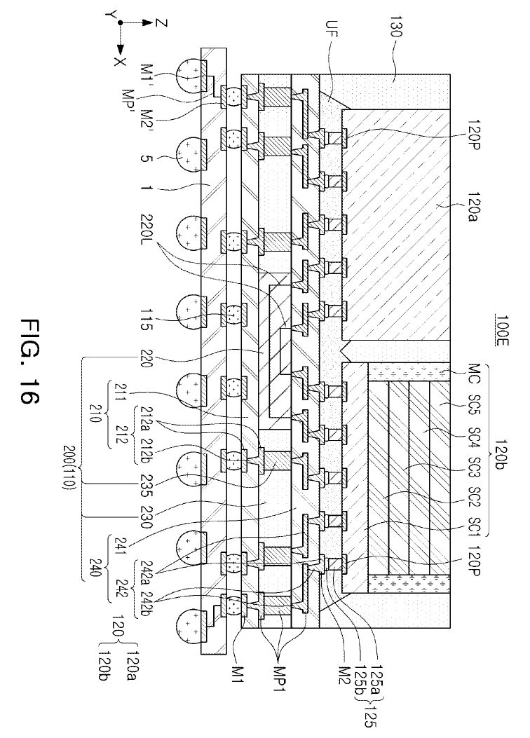

FIG. 15 is a cross-sectional diagram illustrating a semiconductor package according to some example implementations.

Referring to FIG. 15, a semiconductor package 100D in some example implementations may be configured the same as or similar to the example described with reference to FIGS. 3A, 3B, 4, 5, 6, 7, 8, 9, 10, 11, 12, 13 and 14, other than the configuration in which a base substrate 1 and a plurality of semiconductor chips 120 are included. In the example implementations, the substrate 110 may be referred to as an “interposer substrate.” In example implementations, the semiconductor package 100D may further include an underfill layer UF surrounding the bump structures 125. The underfill layer UF may include a thermosetting resin, such as an epoxy resin, and may be formed to encapsulate the bump structures 125 by a capillary underfill (CUF) method.

The base substrate 1 may be a substrate for a semiconductor package including a printed circuit board (PCB), a ceramic substrate, a glass substrate, a tape wiring substrate, or the like. The base substrate 10 may include a lower pad M1’, an upper pad M2’, and a connection circuit MP’. The lower pad M1’ and the upper pad M2’ may include an alloy including at least one metal or two or more metals from among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn). The connection circuit MP’ may be formed of a material similar to that of the lower pad M1’ and the upper pad M2’. The lower pad M1’ may be electrically connected to a module substrate, a system board, or the like, through an external connection bump 5. The upper pad M2’ may be electrically connected to the substrate 110 through a connection bump 115.

In some example implementations, the lower pad M1’, the upper pad M2’, and the connection circuit MP’ may include copper (Cu). At least one of the lower pad M1’, the upper pad M2’, or the connection circuit MP’ may have a work function (less than 4.4 eV) lower than a work function of copper (Cu) (about 4.4 eV to about 4.9 eV).

A plurality of semiconductor chips 120 may be disposed adjacently to each other in a horizontal direction (e.g., the X-direction). The plurality of semiconductor chips 120 may be connected to each other through redistribution conductors 112 of a substrate 110. The plurality of semiconductor chips 120 may include a first chip structure 120a and a second chip structure 120b. The first chip structure 120a may include a logic chip such as a central processor (CPU), a graphic processor (GPU), a field programmable gate array (FPGA), a digital signal processor, an encryption processor, a microprocessor, a microcontroller, an analog-to-digital converter, an ASIC, or the like, and the second chip structure 120b may include a memory chip such as a DRAM, an SRAM, a PRAM, a ReRAM, a FeRAM, an MRAM, and a flash memory. In example implementations, the second semiconductor chip 120b may be provided as a high-performance memory device such as high bandwidth memory (HBM), hybrid memory cube (HMC), or the like.

For example, the second chip structure 120b may include a plurality of semiconductor dies SC1, SC2, SC3, SC4, and SC5 and an encapsulate layer MC. The number of the plurality of semiconductor dies SC1, SC2, SC3, SC4, and SC5 may be greater or less than the example illustrated in the drawing. The plurality of semiconductor dies SC1, SC2, SC3, SC4, and SC5 may be stacked in the vertical direction (Z-direction) by a thermocompression bonding method or a hybrid bonding method. The plurality of semiconductor dies SC1, SC2, SC3, SC4, and SC5 may be interconnected through a through silicon via (through silicon via). The plurality of semiconductor dies SC1, SC2, SC3, SC4, and SC5 may include a buffer die (e.g., SC1) and a plurality of memory dies (e.g., SC2, SC3, SC4, and SC5). The encapsulate layer MC may include an insulating material, such as, for example, an epoxy molding compound (EMC).

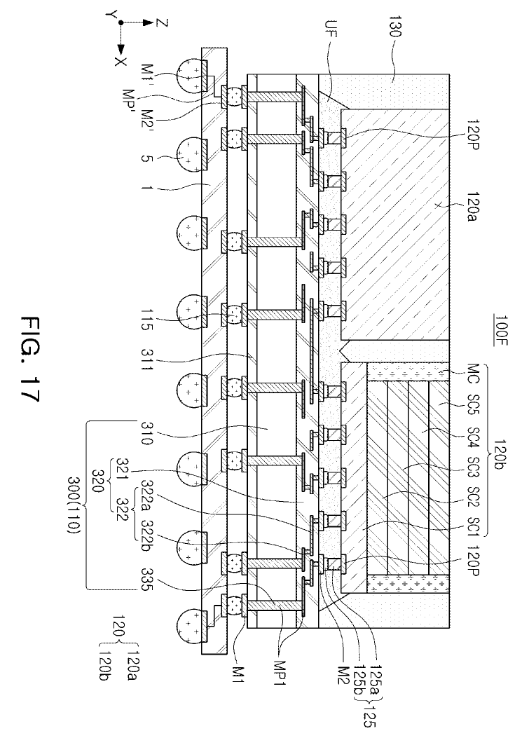

FIG. 16 is a cross-sectional diagram illustrating a semiconductor package 100E according to some example implementations.

Referring to FIG. 16, a semiconductor package 100E in some example implementations may be configured the same as or similar to the examples described with reference to FIGS. 3A, 3B, 4, 5, 6, 7, 8, 9, 10, 11, 12, 13, 14 and 15, other than the configuration in which a first type of interposer substrate 200 is included. The interposer substrate 200 may correspond to the first substrate 110 described with reference to FIG. 3A, or the like. For example, a lower redistribution conductor 212 and an upper redistribution conductor 242 of the interposer substrate 200 described below may be configured similar to the redistribution conductor 112 of the substrate 110 in FIG. 3A described above.

The interposer substrate 200 may include an interconnection chip 220 configured to electrically connect a plurality of semiconductor chips 120. For example, the interposer substrate 200 may include a lower redistribution structure 210, an interconnection chip 220, through-vias 235, a mold 230, and an upper redistribution structure 240.

The lower redistribution structure 210 may include a dielectric layer 211 and a lower redistribution conductor 212. The lower redistribution conductor 212 may include a lower redistribution pattern 212a and a lower redistribution via 212b. The dielectric layer 211 may be formed using a photosensitive resin. For example, the dielectric layer 211 may include a polyimide (PI)-based photosensitive polymer, a polybenzoxazole (PBO)-based photosensitive polymer, a polyhydroxystyrene (PHS)-based photosensitive polymer, a novolak-based photosensitive polymer, a benzocyclobutene (BCB)-based photosensitive polymer, or a photoimageable dielectric (PID).

The lower redistribution pattern 212a may be disposed on or in the dielectric layer 211 and may be electrically connected to the interconnection chip 220, the through-via 235, and the semiconductor chips 120. The lower redistribution pattern 212a may include, for example, copper (Cu), aluminum (Al), silver (Ag), tin (Sn), gold (Au), nickel (Ni), lead (Pb), titanium (Ti), or alloys thereof. The lower redistribution pattern 212a may include a ground pattern, a power pattern, and a signal pattern depending on a design. The signal pattern may provide a transfer path for various signals (e.g., a data signal) other than a ground pattern, a power pattern, or the like. The lower redistribution pattern 212a may include various types of conductive lines extending in the horizontal direction (X and/or Y).

The lower redistribution via 212b may extend vertically in the dielectric layer 211 and may be electrically connected to the redistribution patterns 212a. A side surface of the lower redistribution via 212b may have a tapered shape toward the base substrate 1. The lower redistribution via 212b may include, for example, copper (Cu), aluminum (Al), silver (Ag), tin (Sn), gold (Au), nickel (Ni), lead (Pb), titanium (Ti), or alloys thereof. The lower redistribution via 212b may be a filled via in which a metal material is filled in a via hole or a conformally formed via in which a metal material is formed along an inner wall of the via hole.

The interconnection chip 220 may be disposed on the lower redistribution structure 210. The interconnection chip 220 may include an interconnection circuit 220L for electrically connecting the first chip structure 120a to the second chip structure 120b. The interconnection chip 220 may be a semiconductor chip in which the interconnection circuit 220L is formed on a semiconductor substrate, but example implementations thereof are not limited thereto. In some example implementations, the interconnection circuit 220L may be in a state in which a process of changing a work function is applied.

The through-via 235 may be disposed around the interconnection chip 220 and may be electrically connected to the lower redistribution conductor 212. The through-via 235 may have a post form extending in the vertical direction (Z) to correspond to a thickness of the interconnection chip 220. One surface (e.g., upper surface) of the through-via 235 may be coplanar with one surface (e.g., upper surface) of the mold 230 by a planarization process. The through-via 235 may include copper (Cu), aluminum (Al), silver (Ag), tin (Sn), gold (Au), nickel (Ni), lead (Pb), titanium (Ti), or alloys thereof.

The mold 230 may be disposed between the lower redistribution structure 210 and the upper redistribution structure 240. The mold 230 may be formed to encapsulate the interconnection chip 220 and the through-via 235. The mold 230 may include, for example, a thermosetting resin such as an epoxy resin, a thermoplastic resin such as a polyimide, or a prepreg, ABF, FR-4, BT, EMC, or the like, in which the resins are impregnated with an inorganic pillar.

The upper redistribution structure 240 may include an upper dielectric layer 241, and an upper redistribution conductor 242. The upper redistribution conductor 242 may include an upper redistribution pattern 242a and an upper redistribution via 242b. The upper dielectric layer 241 and the upper redistribution conductor 242 may be configured similarly to the dielectric layer 211 and the lower redistribution conductor 212 described above, and thus, an overlapping description will not be provided. The upper redistribution conductor 242 may be connected to the interconnection circuit 220L through the upper redistribution via 242b. The semiconductor chips 120 may be connected to the interconnection chip 220 through the upper redistribution conductor 242.

In some example implementations, an interposer substrate 200 may include a first metal pad M1, a second metal pad M2, and a metal pattern MP1 provided by the lower redistribution conductor 212, the through-via 235, and the upper redistribution conductor 242. The metal pattern MP1 may be understood as a portion of a conductor including the lower redistribution pattern 212a, the upper redistribution pattern 242a, or the lower redistribution via 212b and the upper redistribution via 242b integrally connected thereto. At least one of the first metal pad M1, the second metal pad M2, or the metal pattern MP1 may receive electrons from the electride and may have a work function lower than a work function of a raw material metal.

FIG. 17 is a cross-sectional diagram illustrating a semiconductor package 100F according to some example implementations.

Referring to FIG. 17, a semiconductor package 100F in some example implementations may be configured the same as or similar to the example described with reference to FIGS. 3A, 3B, 4, 5, 6, 7, 8, 9, 10, 11, 12, 13, 14, 15 and 16, other than the configuration in which a second type of an interposer substrate 300 is included. The interposer substrate 300 may be understood to correspond to the first substrate 110 described with reference to FIG. 3A, or the like. For example, the redistribution conductor 322 of the interposer substrate 300 described below may be configured similar to the redistribution conductor 112 of the substrate 110 in FIG. 3A described above.

The interposer substrate 300 may include a body 310, an interconnection structure 320, and a through-electrode 335. The semiconductor chips 120 may be electrically connected to each other through the interposer substrate 300.

The body 310 may be configured as, for example, one of a silicon, organic, plastic, and glass substrate. When the body 310 is a silicon substrate, the interposer substrate 300 may be referred to as a silicon interposer. An insulating film 311 surrounding a lower portion of the through-electrode 335 may be formed between the body 310 and the first metal pad M1.

The interconnection structure 320 may be disposed on the body 310 and may include an interlayer insulating layer 321 and a single-layer or multilayer redistribution conductor 322. The redistribution conductor 322 may include a redistribution pattern 322a and a redistribution via 322b. The redistribution conductor 322 may include, for example, copper (Cu), aluminum (Al), silver (Ag), tin (Sn), gold (Au), nickel (Ni), lead (Pb), titanium (Ti), or alloys thereof.

The through-electrode 335 may extend through the body 310 and may electrically connect the first metal pad M1 to the second metal pad M2. When the body 310 is a silicon substrate, the through-electrode 330 may be referred to as a TSV.

In some example implementations, the interposer substrate 300 may include a metal pattern MP1 provided by the redistribution conductor 322 and the through-electrode 335. The metal pattern MP1 may be understood as a portion of a conductor including the redistribution pattern 322a or the redistribution via 322b integrally connected thereto. The metal pattern MP1 may electrically connect the first metal pad M1 to the second metal pad M2. At least one of the first metal pad M1, the second metal pad M2, or the metal pattern MP1 may receive electrons from an electride and may have a work function lower than a work function of a raw material metal.

According to example implementations of the present disclosure, a semiconductor package includes a first substrate including a first metal pad, a second metal pad disposed opposite to the first metal pad, and a first metal pattern electrically connecting the first metal pad and the second metal pad; a semiconductor chip disposed on the first substrate and including a connection pad electrically connected to the second metal pad; a mold layer covering the semiconductor chip; and a connection bump disposed on the first metal pad of the first substrate, wherein the first metal pad and the second metal pad include a first metal, and at least one of the first metal pad or the second metal pad has a work function lower than a work function of the first metal.

According to example implementations of the present disclosure, a semiconductor package includes a substrate including a first metal pad, a second metal pad disposed opposite to the first metal pad, and a metal pattern electrically connecting the first metal pad to the second metal pad; and a semiconductor chip including a connection pad disposed on the substrate and electrically connected to the second metal pad, wherein the first metal pad, the second metal pad, and the metal pattern include copper (Cu), and a work function of at least one of the first metal pad, the second metal pad, or the metal pattern is less than 4.4 eV.

According to example implementations of the present disclosure, a semiconductor package includes a substrate including a first metal pad, a second metal pad disposed opposite to the first metal pad, and a metal pattern electrically connecting the first metal pad to the second metal pad; and a semiconductor chip including a connection pad disposed on the substrate and electrically connected to the second metal pad, wherein the semiconductor chip further includes a semiconductor substrate on which an individual device is disposed, a metal wiring disposed between the connection pad and the semiconductor substrate and electrically connecting the connection pad to the individual device, and an interlayer insulating layer covering the individual device and the metal wiring, wherein the first metal pad, the second metal pad, the metal pattern, and the metal wiring include the first metal, and wherein at least one of the first metal pad, the second metal pad, the metal pattern, or the metal wiring has a work function lower than a work function of the first metal.

According to the aforementioned example implementations, by controlling a work function of a metal layer using an electride, a method of manufacturing a metal layer having increased oxidation resistance and a method of manufacturing a semiconductor package may be provided.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the example implementations have been illustrated and described above, it will be configured as apparent to those skilled in the art that modifications and variations could be made without departing from the scope of the present disclosure as defined by the appended claims.

What is claimed is:

1. A method of manufacturing a metal layer, the method comprising:
contacting an electride layer and a metal layer with each other; and
reducing the metal layer by annealing the electride layer and the metal layer.

2. The method of claim 1, wherein the electride layer includes an ionic compound having a work function lower than a work function of the metal layer.

3. The method of claim 2, wherein the electride layer includes at least one of calcium nitride, strontium nitride, barium nitride, yttrium carbide, gadolinium carbide, hafnium sulfide, titanium sulfide, or calcium oxide-alumina.

4. The method of claim 1, wherein the electride layer may has a form of bulk, single crystal or thin film.

5. The method of claim 1, wherein the metal layer includes at least one of copper, aluminum, iron, silver, tin, gold, nickel, lead, or titanium.

6. The method of claim 1, wherein the electride layer and the metal layer are in contact with each other under a vacuum condition.

7. The method of claim 1, wherein the annealing is performed in a thermal environment of 100°C to 800°C.

8. The method of claim 1, wherein the annealing is performed under a vacuum condition.

9. The method of claim 1,
wherein the electride layer includes gadolinium carbide, and
wherein the metal layer includes copper.

10. The method of claim 9, wherein the metal layer has a work function lower than a work function of copper.

11. The method of claim 9, wherein a work function of the metal layer is less than 4.4 eV.

12. A method of manufacturing a semiconductor package, the method comprising:
forming a first metal pad on a carrier substrate;
forming a metal pattern on the first metal pad;
forming a second metal pad on the metal pattern, the second metal pad electrically connected to the first metal pad through the metal pattern; and
performing a process of changing a work function to at least one of the first metal pad, the second metal pad, or the metal pattern,
wherein the process of changing the work function includes contacting an electride layer with at least one of the first metal pad, the second metal pad, or the metal pattern, and then performing annealing.

13. The method of claim 12, wherein the process of changing the work function is performed immediately after one of forming the first metal pad, forming the metal pattern, or forming the second metal pad.

14. The method of claim 12, wherein at least one of the first metal pad, the second metal pad, or the metal pattern to which the process of changing the work function is applied has a work function lower than a work function of a raw-material metal thereof.

15. The method of claim 12, wherein the first metal pad, the second metal pad, and the metal pattern include at least one of copper, aluminum, iron, silver, tin, gold, nickel, lead, or titanium.

16. The method of claim 12, wherein the electride layer includes at least one of calcium nitride, strontium nitride, barium nitride, yttrium carbide, gadolinium carbide, hafnium sulfide, titanium sulfide, or calcium oxide-alumina.

17. The method of claim 12, wherein the annealing is performed in a thermal environment of 100°C to 300°C.

18. The method of claim 12,
wherein the electride layer includes gadolinium carbide,
wherein at least one of the first metal pad, the second metal pad, or the metal pattern to which the process of changing a work function is applied includes copper, and
wherein at least one of the first metal pad, the second metal pad, or the metal pattern to which the process of changing the work function is applied has a work function lower than a work function of copper.

19. A method of manufacturing a metal layer, the method comprising:
allowing an electride layer and a metal layer to be in contact with each other; and
reducing metal layer by annealing the electride layer and the metal layer,
wherein a work function of the metal layer after the annealing is lower than a work function of the metal layer before the annealing.

20. The method of claim 19,
wherein the electride layer includes gadolinium carbide, and
wherein the metal layer includes copper.
